(19) United States
(12) Patent Application Publication
(10) Pub. No.: US 2019/0309411 A1
(43) Pub. Date: Oct. 10, 2019

(54) METHOD AND SYSTEM FOR LOW TEMPERATURE ALD

(71) Applicant: RASIRC, Inc., San Diego, CA (US)

(72) Inventors: Jeffrey J. Spiegelman, San Diego, CA (US); Daniel Alvarez, JR., Oceanside, CA (US); Jian Yang, San Diego, CA (US); Russell J. Holmes, San Diego, CA (US); Edward Heinlein, San Diego, CA (US); Christopher Ramos, Bonita, CA (US); Jeremiah Trammel, San Diego, CA (US)

(21) Appl. No.: 16/393,123

(22) Filed: Apr. 24, 2019

Related U.S. Application Data
(63) Continuation-in-part of application No. PCT/US2017/060650, filed on Nov. 8, 2017.
(60) Provisional application No. 62/419,029, filed on Nov. 8, 2016.
(60) Provisional application No. 62/428,859, filed on Dec. 1, 2016.
(60) Provisional application No. 62/447,425, filed on Jan. 17, 2017.
(60) Provisional application No. 62/661,994, filed on Apr. 24, 2018.

(51) Int. Cl. C23C 16/02; C01B 21/068; C01B 21/076; C23C 16/34; C23C 16/455

(52) U.S. Cl. CPC C23C 16/0272; C01B 21/068; C23C 16/45536; C23C 16/345; C01B 21/0763

(57) ABSTRACT

A method and chemical delivery system are provided for low temperature atomic layer deposition. Thus, methods of forming nitrogen-containing thin films by atomic layer deposition using a substantially water free hydrazine gas and plasma treatment are provided.

### CROSS REFERENCE TO RELATED APPLICATION(S)

This application is a continuation-in-part of International Application No. PCT/US2017/060650, filed Nov. 8, 2017, which claims the benefit of priority under 35 U.S.C. § 119(e) of U.S. Ser. No. 62/419,029, filed Nov. 8, 2016, to U.S. Ser. No. 62/428,859, filed Dec. 1, 2016, and to U.S. Ser. No. 62/447,425, filed Jan. 17, 2017. This application also claims the benefit of priority under 35 U.S.C. § 119(e) of U.S. Ser. No. 62/661,994, filed Apr. 24, 2018. The entire content of each of these applications is incorporated herein by reference.

### BACKGROUND OF THE INVENTION

### Field of the Invention

Methods and systems for the vapor phase delivery of high purity process gases in micro-electronics and other critical process applications.

### Background Information

The demand for faster, smaller and more energy efficient logic devices as well as higher density, higher speed, and increased reliability for advanced memory devices has led to numerous challenges in Semiconductor device manufacturing. Novel metal materials, 3D architecture and increasing High-Aspect-Ratio (HAR) structures are being used to address these challenges, however this has placed additional constraints on film deposition methods.

Various process gases may be used in the manufacturing and processing of micro-electronics. In addition, a variety of chemicals may be used in other environments demanding high purity gases, e.g., critical processes or applications, including without limitation microelectronics applications, wafer cleaning, wafer bonding, photoresist stripping, silicon oxidation, surface passivation, photolithography mask cleaning, atomic layer deposition, chemical vapor deposition, flat panel displays, industrial parts cleaning, pharmaceutical manufacturing, production of nano-materials, power generation and control devices, fuel cells, power transmission devices, and other applications in which process control and purity are critical considerations. In those processes and applications, it is necessary to deliver specific amounts of certain process gases under controlled operating conditions, e.g., temperature, pressure, and flow rate.

Deposition of silicon nitride films having desired characteristics by thermal atomic layer deposition (ALD) processes using reduced thermal budgets can be difficult with traditional Ammonia based processes (e.g., such as at reduced temperatures, including at temperatures of less than about 600° C.). Emerging processes for advanced applications have thermal constraints of a maximum 450° C., where a maximum of 350° C. is anticipated in the near future. Silicon nitride-based films deposited by current plasma processes (e.g., plasma enhanced ALD (PEALD)) performed at reduced temperatures (<450° C.) may result in films having undesirably low conformality on high aspect ratio structures and 3-dimensional surfaces. In addition, surface damage to the underlying structures, and/or undesirably low film quality inside three-dimensional structures is problematic. Without being bound by theory, the low conformality and/or reduced film quality may be due to the anisotropic nature of direct plasmas. Silicon nitride based films formed using current methods may also undesirably demonstrate high etch rates and/or have low etch selectivity to another different material in a semiconductor device (e.g., a thermal silicon oxide material, TOX), such that the silicon nitride film cannot withstand one or more subsequent thermal silicon oxide etch steps used in the device fabrication process.

With respect to silicon nitride (SiN), for example, ammonia (NH₃) is often used at temperatures in excess of 500° C. or more typically >600° C. However, today's state of the art chip design fabrication techniques incorporating new three-dimensional structures with new materials, multiple metal and dielectric layers on very thin atomic structures, are not compatible with the high temperatures needed to make SiN with ammonia. At lower temperatures, ammonia is slow to react, forms porous films and incorporates multiple contaminants leading to device failures. It would be preferable to deposit at lower temperatures. Early studies have shown the potential viability of Hydrazine (N₂H₄) and its derivatives as a low temperature Nitrogen source in thermal ALD. Thus, hydrazine presents an opportunity to explore lower temperatures in part because of the favorable thermodynamics of hydrazine resulting in lower deposition temperatures and a spontaneous reaction to form nitrides. Although reported in the literature (Burton et al. J. Electrochem. Soc., 155(7) 0508-0516 (2008)), hydrazine usage has not been adopted commercially due to significant safety concerns with using hydrazine. Substituted hydrazines, which are perceived to be safer than hydrazine, suffer from the drawback of leading to unwanted carbon contamination. Further, because hydrazine is highly hygroscopic, water contamination is another difficult problem that requires consistent control to sufficiently grow SiN films at lower temperatures. Thus, there is a need to develop a safer and higher purity method for using hydrazine for either deposition processes or for delivery to other critical process applications.

As explained in International Publication Nos. WO2016/065132 and WO2017/181013, and PCT App. No. PCT/US2018/022686 by Rasirc, Inc., which are hereby incorporated by reference herein, the gas phase use of hydrazine has been limited by safety, handling, and purity concerns. Since anhydrous hydrazine has a low flash point of about 37° C. and can be explosive, Semiconductor industry protocol for safe handling of this material is very limited. Therefore, a technique is needed to overcome these limitations and, specifically, to provide substantially water-free gaseous hydrazine suitable for use in micro-electronics and other critical process applications.

### SUMMARY OF THE INVENTION

The present invention is based on delivering a substantially water-free process gas stream, particularly a hydrazine-containing gas stream to a system for growing thin films on a substrate. The methods and systems are particularly useful in micro-electronics applications and other critical processes.

Accordingly, the present invention provides methods of making nitrogen-containing thin films, e.g., thin films for semiconductor materials (particularly silicon nitride and titanium nitride), using hydrazine delivered to a thin film manufacturing process (such as atomic layer deposition (ALD)). Thus, the invention provides a method of growing a thin film. The method includes providing a substrate within a chamber heated to about 300° C.-410° C., pre-treating the substrate with anhydrous hydrazine, thereby creating silicon nitride bonds on a surface of the substrate, performing a cycle for layer deposition on the pre-treated substrate, thereby depositing a layer of SiN onto the surface of the substrate, wherein the deposited layer forms a film that is substantially oxygen free. In various embodiments, the cycle for layer deposition includes exposing the substrate to one or more silicon precursors, such as hexachlorodisilane (Si₂Cl₆), thereafter, exposing the substrate to anhydrous hydrazine, and thereafter, exposing the substrate to plasma. In various embodiments, the step of performing a cycle for layer deposition is repeated to increase thickness on the substrate, such as repeating the step about 20-450 times. In various embodiments, the step of performing a cycle for layer deposition is repeated 400 times. In certain embodiments, the cycle includes a nitrogen purge following each of the aforementioned exposing steps. In various embodiments, the step of contacting with plasma may be performed after multiple A-B cycles that do not individually include a plasma step, may be performed as a termination step to complete the ALD process, or may be performed as an intermediate step after a sufficient number of A-B cycles followed by another set of AB cycles.

In various embodiments, exposure to the silicon precursor occurs at about 0.01-10 Torr, for example at about 0.55 Torr for about 1 second. In various embodiments, exposure to anhydrous hydrazine occurs at about 0.01-10 Torr, for example at about 0.6 Torr for about 0.5-10 seconds. In various embodiments, exposure to plasma includes exposure to argon plasma for about 1-10 seconds. In various embodiments, the chamber is heated to about 300° C.-410° C. In one particular embodiment, the step of performing a cycle for layer deposition includes exposure to hexachlorodisilane at about 0.55 Ton for about 1 second, exposure to a first nitrogen purge for 30 seconds, exposure to anhydrous hydrazine at about 0.6 Ton for about 0.5 seconds, exposure to a second nitrogen purge for 30 seconds, and exposure to argon plasma for about 1-10 seconds.

In various embodiments, the silicon precursor is independently selected from the group consisting of hexachlorodisilane, chlorosilane (SiH₃Cl), dichlorosilane (SiH₂Cl₂), trichlorosilane (SiHCl₃), silicon tetrachloride (SiCl₄), Octachlorotrisilane (Si₃Cl₈), silicon tetrabromide (SiBr₄), silicon tetraiodide (SiI₄), other silicon halides or silanes containing pseudohalogen(s), trisilylamine (TSA), tris(dimethylamino)silane (3DMAS), Bis(tertiary-butylamino)silane (BTBAS) and di(sec-butylamino)silane (DSBAS), di(isopropylamino)silane (DIPAS), bis(diethylamino)silane (BDEAS), tris(isopropylamino)silane (TIPAS), other organoaminosilanes, silane (SiH₄), disilane (Si₂H₆), trisilane (Si₃H₈), neopentasilane (NPS, Si₅H₁₂), other silanes or substituted silanes containing multiple Si atoms, dimethylaminochlorosilane, tertiary-butylaminobromosilane, other organoaminosilanes containing halogen(s) or pseudohalogen(s), trimethylsilyl amine, trimethylsilyl dimethylamine, other alkylsilyl amines.

In various embodiments, the anhydrous hydrazine is delivered in a gas stream produced from a non-aqueous hydrazine solution that contains less than about 50 parts-per-million of water. Thus, the gas stream may have, for example, less than 1 ppm, 100 ppb, 10 ppb or 1 ppb water vapor. Thus, the methods of growing a thin film on a substrate may also include a step of drying the hydrazine solution prior to forming the gas stream, such as, for example, contacting the moisture-containing solution with a purifier media (e.g., alkali metal media) configured to remove impurities and water content therefrom.

In another aspect, the invention provides a method of growing a thin film. The method steps are identical to those described above, but the cycle for layer deposition on the pre-treated substrate includes exposing the substrate to a titanium precursor, such as titanium tetrachloride (TiCl₄), thereafter, exposing the substrate to anhydrous hydrazine, and thereafter, exposing the substrate to plasma. In various embodiments, the step of performing a cycle for layer deposition is repeated to increase thickness on the substrate, such as repeating the step about 20-450 times. In various embodiments, the step of performing a cycle for layer deposition is repeated 400 times. In certain embodiments, the cycle includes a nitrogen purge following each of the aforementioned exposing steps. In various embodiments, the step of contacting with plasma may be performed after multiple A-B cycles that do not individually include a plasma step, may be performed as a termination step to complete the ALD process, or may be performed as an intermediate step after a sufficient number of A-B cycles followed by another set of AB cycles.

In various embodiments, the titanium precursor is independently selected from the group consisting of titanium tetrachloride (TiCl₄), other titanium halides, titanium isopropoxide (TTIP), tetrakis(dimethylamino)titanium (TDMAT), tetrakis(diethylamino)titanium (TDEAT), tetrakis(ethylmethylamino)titanium (TEMAT), tri(dimethylamino)-(dimethylamine-2-propanolato)titanium (TDMADT) and cyclopentadienyl-based titanium derivatives.

In various embodiments, exposure to the titanium precursor occurs at about 0.4-0.6 Ton, for example at about 0.55 Torr for about 1 second. In various embodiments, exposure to anhydrous hydrazine occurs at about 0.5-0.65 Ton, for example at about 0.6 Torr for about 0.5-10 seconds. In various embodiments, exposure to plasma includes exposure to argon plasma for about 1-10 seconds. In various embodiments, the chamber is heated to about 300° C.-410° C. In one particular embodiment, the step of performing a cycle for layer deposition includes exposure to titanium tetrachloride at about 0.55 Torr for about 1 second, exposure to a first nitrogen purge for 30 seconds, exposure to anhydrous hydrazine at about 0.6 Torr for about 0.5 seconds, exposure to a second nitrogen purge for 30 seconds, and exposure to argon plasma for about 1-10 seconds.

In certain embodiments, the hydrazine solution comprises substantially pure hydrazine, meaning hydrazine in which no other chemicals are deliberately included but allowing for incidental amounts of impurities. In certain embodiments, the solution comprises from about 5% to about 99% by weight of hydrazine, or from about 90% to about 99%, from about 95% to about 99%, from about 96% to about 99%, from about 97% to about 99%, from about 98% to about 99%, or from about 99% to about 100% by weight of hydrazine, with the remaining components comprising solvents and/or stabilizers. In some embodiments, the solution comprises hydrazine at concentrations greater than 99.9% purity and, in some embodiments, the solution comprises hydrazine at concentrations of greater than 99.99%. Selection of an appropriate non-aqueous hydrazine solution will be determined by the requirements of a particular application or process.

In certain embodiments, the hydrazine solution comprises, in addition to hydrazine, one or more suitable solvents. In one example, the non-aqueous hydrazine solution comprises a glycol solvent, e.g., ethylene glycol, triethylene glycol, α-propylene glycol, and β-propylene glycol. A particular non-aqueous hydrazine solution that is useful in the methods and systems described herein is 65% hydrazine/35% triethylene glycol. In other examples, the non-aqueous hydrazine solution comprises an alcohol amine, such as ethanol amine, diethanol amine, or triethanolamine. In other examples, the non-aqueous hydrazine solution comprises an aprotic amide solvent, e.g., hexamethylphosoramide, 1,3-Dimethyl-3,4,5,6-tetrahydro-2(1H)-pyrimidinone (DMPU), 1,3-Dimethyl-2-imidazolidinone (DMEU), tetramethylurea, or another aprotic urea-based solvent. Another solvent is hexamethylenetetramine. The non-aqueous hydrazine solution may comprise a PEGylated solvent, wherein the PEGylated solvent is a liquid when at a temperature of about 25° C. The term “PEGylated solvent” refers to a solvent containing a covalently attached poly(ethylene glycol) moiety. One exemplary PEGylated solvent is poly(ethylene glycol) dimethyl ether. In some embodiments, the suitable solvent is selected from low molecular weight polymers or oligomers of polyaniline, polypyrrole, polypyridine or polyvinylalchohol. A low molecular weight polymer is one such that when combined with hydrazine, the combined solution has a viscosity of about 35 centipoises (cp) or less. Other examples of solvents include glymes such as monoglyme, diglyme, triglyme, higlyme, and tetraglyme. Those of skill in the art will recognize that other solvents may be useful in the methods, systems, and devices disclosed herein. Criteria for selected an appropriate solvent include miscibility and solubility with hydrazine, chemical compatibility with hydrazine, compatibility with other components of the system (such as a membrane), boiling point of the solvent, flash point of the non-aqueous hydrazine solution, and other safety and handling concerns.

Further examples include a range of PEGylated dimethyl ethers such as Polyglycol DME 200, Polyglycol DME 250, Polyglycol DME 500, Polyglycol DME 1000, or Polyglycol DME 2000. In some embodiments, the non-aqueous hydrazine solution comprises from about 30% to about 69% by weight and ranges in between including between about 65% to about 69% by weight of hydrazine. The remainder of the solution may comprise, for example, one or more PEGylated solvents such as poly(ethylene glycol) dimethyl ether. For instance, the hydrazine solution may comprise from about 32% to 35% by weight of PEGylated solvent such as poly(ethylene glycol) dimethyl ether or other suitable solvents. In other embodiments, less than about 65% hydrazine is used and more than about 35% of a PEGylated solvent such as poly(ethylene glycol) dimethyl ether is used such as Polyglycol DME 250.

The methods and systems provided herein may further comprise removing one or more components from the hydrazine containing gas stream to produce a purified hydrazine containing gas stream, e.g., using a device that selectively or non-selectively removes components from the gas stream. Preferred devices would be devices that substantially remove a non-reactive process gas from the hydrazine containing gas stream, while the amount of hydrazine in the gas stream is relatively unaffected. For example, a device may remove any non-aqueous solvents or stabilizers from the gas stream, including without limitation any traces of water or non-aqueous solvents. For example, the devices may further comprise a purifier positioned downstream of the head space. Particularly preferred purifier devices are membrane contactors, molecular sieves, activated charcoal and other adsorbents, if they have the desired characteristics to meet the application or process requirements. A preferred characteristic of the gas removal device is the ability to remove certain component(s) in a relatively selective manner while allowing the remaining component(s) to remain in the hydrazine gas stream relatively unaffected.

The methods and systems provided herein may further comprise use of various components for containing and controlling the flow of the gases and liquids used therein. For example, the methods and systems may further comprise mass flow controllers, valves, check valves, pressure gauges, regulators, rotameters, and pumps. The methods and systems provided herein may further comprise various heaters, thermocouples, and temperature controllers to control the temperature of various components of the systems and steps of the methods.

Additional objects and advantages of the invention will be set forth in part in the description which follows, and in part will be obvious from the description, or maybe learned by practice of the invention. The objects and advantages of the invention will be realized and attained by means of the elements and combinations particularly pointed out in the embodiments and claims.

It is to be understood that both the foregoing general description and the following detailed description are exemplary and explanatory only and are not restrictive of the invention.

The accompanying drawings, which are incorporated in and constitute a part of this specification, illustrate several embodiments of the invention and, together with the description, serve to explain the principles of the invention.

### BRIEF DESCRIPTION OF THE DRAWINGS

FIG. 1 is a pictorial diagram showing an exemplary process for growing a thin film on a substrate.

FIGS. 2A and 2B are graphical diagrams showing the concentration of several species determined by x-ray photoelectron spectroscopy (XPS) on a silicon-germanium semiconductor (Si_{0.5}Ge0.5(110), FIG. 2A; Si_{0.7}Ge0.3(001), FIG. 2B) after different steps of a silicon nitride ALD growth process.

FIG. 3 is a pictorial diagram showing an exemplary embodiment of a system for fabricating a thin film.

FIGS. 4A and 4B are graphical diagrams showing an exemplary process for growing a thin film on a substrate.

FIGS. 5A and 5B are graphical diagrams showing the results from XPS chemical composition analysis of 100 cycles of TBTDET and N₂H₄ at 100° C., 150° C., and 300° C. (FIG. 5A). 15 minutes of atomic H were enough to remove the carbon that was accumulating on the surface during deposition (FIG. 5B).

FIG. 6 is a graphical diagram showing the results from an XPS saturation study of TiCl₄ and N₂H₄ on clean Sift. Initial 1×TiCl₄ dose deposited 2.2% Cl and 0.5% Ti on UHV annealed SiO₂/Si. Additional 2×TiCl₄ saturated Cl at 2.4% and Ti at 0.6%. Similarly, a 1×, 2×, and 3× dose of N₂H₄ were performed, which saturated the Cl at 1.4% and N at 0.8%. Self-limiting exposures were consistent with ALD.

FIG. 7 is a graphical diagram showing normalized and corrected XPS of 40 cycles TiNx at 300° C. on a UHV annealed surface.

FIGS. 8A-8D are graphical diagrams showing XPS data comparing NH₃ vs N₂H₄ grown TiNx films: 40 cycles TiNx at 400° C. grown with NH₃ (FIG. 8A) and N₂H₄ (FIG. 8B), with corresponding resistance measurements (FIGS. 8C and 8D, respectively). The amount of O and C was ˜2× larger with the Cl being 50% higher in NH₃ grown films.

### DETAILED DESCRIPTION OF THE INVENTION

Various embodiments of the invention will now be explained in greater detail. It is to be understood that both the foregoing general description and the following detailed description are exemplary and explanatory only, and are not restrictive of the invention as claimed. Any discussion of certain embodiments or features serves to illustrate certain exemplary aspects of the invention. The invention is not limited to the embodiments specifically discussed herein.

Unless otherwise indicated, all numbers such as those expressing temperatures, weight percents, concentrations, time periods, dimensions, and values for certain parameters or physical properties used in the specification and claims are to be understood as being modified in all instances by the term “about.” It should also be understood that the precise numerical values and ranges used in the specification and claims form additional embodiments of the invention. All measurements are subject to uncertainty and experimental variability.

The term “critical process or application” as used herein is a broad term, and is to be given its ordinary and customary meaning to a person of ordinary skill in the art (and is not to be limited to a special or customized meaning), and refers without limitation to a process or application in which process control and purity are critical considerations. Examples of critical processes and applications include without limitation microelectronics applications, wafer cleaning, wafer bonding, photoresist stripping, silicon oxidation, surface passivation, photolithography mask cleaning, atomic layer deposition, chemical vapor deposition, flat panel displays, disinfection of surfaces contaminated with bacteria, viruses and other biological agents, industrial parts cleaning, pharmaceutical manufacturing, production of nano-materials, power generation and control devices, fuel cells, and power transmission devices.

The term “process gas” as used herein is a broad term, and is to be given its ordinary and customary meaning to a person of ordinary skill in the art (and is not to be limited to a special or customized meaning), and refers without limitation to a gas that is used in an application or process, e.g., a step in the manufacturing or processing of micro-electronics and in other critical processes. Exemplary process gases are reducing agents, oxidizing agents, inorganic acids, organic acids, inorganic bases, organic bases, and inorganic and organic solvents. A preferred process gas is hydrazine.

The term “reactive process gas” as used herein is a broad term, and is to be given its ordinary and customary meaning to a person of ordinary skill in the art (and is not to be limited to a special or customized meaning), and refers without limitation to a process gas that chemically reacts in the particular application or process in which the gas is employed, e.g., by reacting with a surface, a liquid process chemical, or another process gas.

The term “non-reactive process gas” as used herein is a broad term, and is to be given its ordinary and customary meaning to a person of ordinary skill in the art (and is not to be limited to a special or customized meaning), and refers without limitation to a process gas that does not chemically react in the particular application or process in which the gas is employed, but the properties of the “non-reactive process gas” provide it with utility in the particular application or process.

The term “carrier gas” as used herein is a broad term, and is to be given its ordinary and customary meaning to a person of ordinary skill in the art (and is not to be limited to a special or customized meaning), and refers without limitation to a gas that is used to carry another gas through a process train, which is typically a train of piping. Exemplary carrier gases are nitrogen, argon, hydrogen, oxygen, CO₂, clean dry air, helium, or other gases that are stable at room temperature and atmospheric pressure.

The term “head space” as used herein is a broad term, and is to be given its ordinary and customary meaning to a person of ordinary skill in the art (and is not to be limited to a special or customized meaning), and refers without limitation to an enclosed space configured to contain a volume of gas in fluid contact with a hydrazine solution that provides at least a portion of the gas contained in the head space. There may be a permeable or selectively permeable barrier wholly or partially separating the head space that is optionally in direct contact with the hydrazine solution. In those embodiments where the membrane is not in direct contact with the hydrazine solution, more than one head space may exist, i.e., a first head space directly above the solution that contains the vapor phase of the solution and a second head space separated from the first head space by a membrane that only contains the components of the first space that can permeate the membrane, e.g., hydrazine. In those embodiments with a hydrazine solution and a head space separated by a substantially gas-impermeable membrane, the head space may be located above, below, or on any side of the hydrazine solution, or the head space may surround or be surrounded by the hydrazine solution. For example, the head space may be the space inside a substantially gas-impermeable tube running through the hydrazine solution or the hydrazine solution may be located inside a substantially gas-impermeable tube with the head space surrounding the outside of the tube.

The term “substantially gas-impermeable membrane” as used herein is a broad term, and is to be given its ordinary and customary meaning to a person of ordinary skill in the art (and is not to be limited to a special or customized meaning), and refers without limitation to a membrane that is relatively permeable to other components that may be present in a gaseous or liquid phase, e.g., hydrazine, but relatively impermeable to other gases such as, but not limited to, hydrogen, nitrogen, oxygen, carbon monoxide, carbon dioxide, hydrogen sulfide, hydrocarbons (e.g., ethylene), volatile acids and bases, refractory compounds, and volatile organic compounds.

The term “ion exchange membrane” as used herein is a broad term, and is to be given its ordinary and customary meaning to a person of ordinary skill in the art (and is not to be limited to a special or customized meaning), and refers without limitation to a membrane comprising chemical groups capable of combining with ions or exchanging with ions between the membrane and an external substance. Such chemical groups include, but are not limited to, sulfonic acid, carboxylic acid, sulfonamide, sulfonyl imide, phosphoric acid, phosphinic acid, arsenic groups, selenic groups, phenol groups, and salts thereof.

Exemplary membranes include, but are not limited to, polymer resins containing exchangeable ions, such as a fluorine-containing polymer, e.g., polyvinylidenefluoride, polytetrafluoroethylene (PTFE), ethylene tetrafluoride-propylene hexafluoride copolymers (FEP), ethylene tetrafluoride-perfluoroalkoxyethylene copolymers (PFE), polychlorotrifluoroethylene (PCTFE), ethylene tetrafluorideethylene copolymers (ETFE), polyvinylidene fluoride, polyvinyl fluoride, vinylidene fluoride-trifluorinated ethylene chloride copolymers, vinylidene fluoride-propylene hexafluoride copolymers, vinylidene fluoride propylene hexafluoride-ethylene tetrafluoride terpolymers, ethylene tetrafluoridepropylene rubber, and fluorinated thermoplastic elastomers. Alternatively, the resin comprises a composite or a mixture of polymers, or a mixture of polymers and other components, to provide a contiguous membrane material. In certain embodiments, the membrane material can comprise two or more layers. The different layers can have the same or different properties, e.g., chemical composition, porosity, permeability, thickness, and the like. In certain embodiments, it can also be desirable to employ a layer (e.g., a membrane) that provides support to the filtration membrane, or possesses some other desirable property.

The term “permeation rate” as used herein is a broad term, and is to be given its ordinary and customary meaning to a person of ordinary skill in the art (and is not to be limited to a special or customized meaning), and refers without limitation to the rate at which a specific chemical, e.g., hydrazine, or a chemical composition a permeates a membrane. The permeation rate may be expressed as an amount of the chemical or composition of interest that permeates a particular surface area of membrane during a period of time, e.g., liters per minute per square inch (L/min/in²).

The term “non-aqueous solution” or “non-aqueous hydrazine solution” as used herein is a broad term, and is to be given its ordinary and customary meaning to a person of ordinary skill in the art (and is not to be limited to a special or customized meaning), and refers to a solution comprising hydrazine and optionally other components and containing less than 10% by weight of water. Exemplary non-aqueous solutions include those containing less than 2%, 0.5%, 0.1%, 0.01%, 0.001% or less water, which solutions are referred to herein as “anhydrous.” Thus, “anhydrous hydrazine” refers to a non-aqueous solution of hydrazine containing less than 2%, 0.5%, 0.1%, 0.01%, 0.001% or less water. Accordingly, the hydrazine solution can be dried to low ppm levels (i.e., <100 ppm), for example, less than 1 ppm, 100 ppb, 10 ppb or 1 ppb water.

The term “stabilizer” as used herein is a broad term, and is to be given its ordinary and customary meaning to a person of ordinary skill in the art (and is not to be limited to a special or customized meaning), and refers to a chemical that prevents the decomposition or reaction of process chemical, such as hydrazine or hydrogen peroxide. In certain embodiments, the stabilizer is non-volatile and is not present in the vapor phase in more than an insubstantial amount. In certain embodiments, the stabilizer can be removed from the process gas stream by exposing the process gas stream to an adsorbent or passing the process gas stream through a cold trap. In certain embodiments that include a membrane separating the non-aqueous hydrazine solution from the vapor phase, the stabilizer may not permeate the membrane.

In various embodiments, hydrazine may be provided in any of the various methods and systems for growing thin films, as described herein, from a hydrazine delivery assembly (HDA). An HDA is a device for delivering hydrazine into a process gas stream, e.g., a carrier gas used in a critical process application, e.g., microelectronics manufacturing or other critical process applications. An HDA may also operate under vacuum conditions. An HDA may have a variety of different configurations comprising at least one membrane and at least one vessel containing a non-aqueous hydrazine solution and a head space separated from the solution by membrane. Thus, the HDA can be filled with a non-aqueous hydrazine containing solution, while maintaining a head space separated from the hydrazine containing solution by a membrane. Because the membrane is permeable to hydrazine and substantially impermeable to the other components of the solution, the head space will contain substantially pure hydrazine vapor in a carrier gas or vacuum, depending upon the operating conditions of the process. An exemplary HDA can be constructed similarly to the devices described in commonly assigned U.S. Pat. No. 7,618,027, which is herein incorporated by reference.

Accordingly, the present invention provides a method of growing thin films using vapor deposition processes, such as but not limited to, chemical vapor deposition (CVD) or ALD. Since hydrazine is highly reactive at temperatures below 400° C., it displays higher growth rates, density and resistivity when used in direct thermal nitridation of silicon, and therefore may be used to reduce solid-state diffusion and form an abrupt insulator-semiconductor interface and etch stops, multiple patterning, titanium nitride electrodes, tungsten nitride barrier layers, and barrier layers for copper. Thus, hydrazine finds use in the passivation of III-V semiconductors, such as GaN. The low-temperature nitridation of numerous transition metal nitrides (e.g., Co, Cr, Fe, Mo, Si, Ta, Ti, V, and W) by reaction with hydrazine is also contemplated. Thus, the output of an HDA may be provided in fluid communication with a deposition chamber, such as an atomic layer deposition chamber, which is configured to hold a substrate for depositing materials thereupon.

A “substrate surface,” as used herein, refers to any substrate or material surface formed on a substrate upon which film processing is performed during a fabrication process within the deposition chamber. For example, a substrate surface on which processing can be performed includes materials such as silicon, silicon oxide, strained silicon, silicon on insulator (SOI), siliconoxynitride (SiON), carbon doped silicon oxides, silicon nitride, doped silicon, germanium, titantium nitride (TiN), gallium arsenide, glass, sapphire, and any other materials such as metals, metal nitrides, metal alloys, and other conductive materials, depending on the application. Barrier layers, metals or metal nitrides on a substrate surface include titanium, titanium nitride, tungsten nitride, tantalum and tantalum nitride, aluminum, copper, or any other conductor or conductive or non-conductive barrier layer useful for device fabrication. Substrates on which embodiments of the invention may be useful include, but are not limited to semiconductor wafers, such as crystalline silicon (e.g., Si<100> or Si<111>), silicon oxide, strained silicon, silicon germanium, doped or undoped polysilicon, doped or undoped silicon wafers, numerous transition metal nitrides such as Co, Cr, Fe, Mo, Si, Ta, Ti, V, and W, etc., and patterned or non-patterned wafers. Substrates may be exposed to a pretreatment process to clean, polish, etch, reduce, oxidize, hydroxylate, anneal and/or bake the substrate surface.

In various embodiments, the substrate can be processed in a single substrate deposition chamber, where a single substrate is loaded, processed and unloaded before another substrate is processed. The substrate can also be processed in a continuous manner, like a conveyer system, in which multiple substrates are individually loaded into a first part of the chamber, moved through the chamber and are unloaded from a second part of the chamber. Additionally, the processing chamber may be a carousel in which multiple substrates are moved about a central axis and are exposed to deposition, etching, annealing, cleaning, and other processes throughout the carousel path. Optionally, the substrate may be cleaned and/or pre-treated with hydrazine prior to processing.

In some embodiments, a process of fabricating a thin film can include a combination of a thermal ALD process and a plasma treatment, such as argon plasma treatment. For example, the process can include a thermal ALD process followed by argon plasma treatment. The number of repetitions of the thermal ALD process, the number of repetitions of the plasma treatment, and/or the process parameters of the thermal ALD process and/or the process parameters of the plasma treatment, can be optimized to provide a thin film having desired characteristics (e.g., including formation of films having desired characteristics on three-dimensional (3-D) structures). This enables the low density thermal ALD film to be densified by the plasma so the wet etch rate is comparable to a film grown by PEALD (plasma enhanced ALD). In this way films can be grown on 3-dimensional and high aspect ratio structures common in memory and logic devices.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In various embodiments, the gases (either reactive gases or inert gases) being employed are heated or cooled to locally change the substrate temperature. In some embodiments, a heater/cooler is positioned within the chamber adjacent to the substrate surface to convectively change the substrate temperature. In various embodiments, the layer deposition process is performed at reduced temperatures (e.g., less than about 450° C., such as about 300° C.-425° C., and for example, about 300° C.-410° C.).

The substrate can also be stationary or rotated during processing. A rotating substrate can be rotated continuously or in discreet steps. For example, a substrate may be rotated throughout the entire process, or the substrate can be rotated by a small amount between exposure to different reactive or purge gases. Rotating the substrate during processing (either continuously or in steps) may help produce a more uniform deposition or etch by minimizing the effect of, for example, local variability in gas flow geometries.

In various embodiments, the process gas being delivered during processing is hydrazine, which is delivered in a gas stream produced from a non-aqueous hydrazine solution that contains less than about 50 parts-per-million of water, as described above. Thus, the gas stream may have, for example, less than 1 ppm, 100 ppb, 10 ppb or 1 ppb water vapor. Thus, the methods of growing a thin film on a substrate may also include a step of drying the hydrazine solution prior to forming the gas stream, such as, for example, contacting the moisture-containing solution with a purifier media (e.g., alkali metal media) configured to remove impurities and water content therefrom.

As described herein, the drying step may include subjecting the hydrazine solution to one or more of static and column drying methods, while the solvent may be separately subjected to a drying method prior to mixing with the hydrazine solution. In various embodiments, an automated drying method may be implemented for the hydrazine solution, solvent, or both. Accordingly, both the hydrazine solution and the solvent can be dried to low ppm levels (i.e., <100 ppm). In various embodiments, the processing (layer deposition) steps may be repeated a plurality of times to increase thickness of the resulting thin film. The resulting thin film grown by the systems and methods disclosed herein may therefore be substantially free of contamination and/or substantially oxygen-free.

Thus, in various embodiments, the method of growing thin films containing nitrogen includes providing a substrate within a chamber, optionally contacting the substrate with hydrazine to create silicon nitride bonds on a surface of the substrate, contacting the substrate with a silicon precursor (referred to as step “A”), such as hexachlorodisilane (HCDS), to deposit a layer of SiN onto the surface of the substrate, thereafter, contacting the substrate with anhydrous hydrazine (referred to as step “B”), and contacting the substrate and the deposited layer with plasma to form film that is substantially oxygen free. The method may further include purging the chamber with nitrogen gas between each of the contacting steps A-B for a pre-determined amount of time prior to commencing the next step. For example, after contacting with hydrazine as a pre-treatment step, the substrate may be exposed to HCDS for about 1 s, followed by a 30 s nitrogen purge, followed by contact with anhydrous hydrazine for a predetermined amount of time, followed by a 30 s nitrogen purge, and contacting with argon plasma for about 1-10 s, where each of the processing steps is performed at about 300° C.-410° C. In various embodiments, the HCDS is provided at about 0.4-0.6 Torr, for example at 0.55 Ton. In various embodiments, the hydrazine is provided at about 0.5-0.65 Torr, for example at 0.6 Ton. The cycle of processing steps may be repeated about 20-450 times, such as about 95-400 cycles. In various embodiments, the processing includes 400 cycles. Alternatively, the step of contacting with plasma may be performed after multiple A-B cycles that do not individually include a plasma step, may be performed as a termination step to complete the ALD process, or may be performed as an intermediate step after a sufficient number of A-B cycles followed by another set of AB cycles. For example, a process following the sequence ABABAB-Plasma-ABABAB-Plasma is likely to result in high-quality film properties and increase process throughput.

Exemplary silicon precursors include, but are not limited to, hexachlorodisilane, chlorosilane (SiH₃Cl), dichlorosilane (SiH₂Cl₂), trichlorosilane (SiHCl₃), silicon tetrachloride (SiCl₄), Octachlorotrisilane (Si₃Cl₈), silicon tetrabromide (SiBr₄), silicon tetraiodide (SiI₄), other silicon halides or silanes containing pseudohalogen(s), trisilylamine (TSA), tris(dimethylamino)silane (3DMAS), Bis(tertiary-butylamino)silane (BTBAS) and di(sec-butylamino)silane (DSBAS), di(isopropylamino)silane (DIPAS), bis(diethylamino)silane (BDEAS), tris(isopropylamino)silane (TIPAS), other organoaminosilanes, silane (SiH₄), disilane (Si₂H₆), trisilane (Si₃H₈), neopentasilane (NPS, Si₅H₁₂), other silanes or substituted silanes containing multiple Si atoms, dimethylaminochlorosilane, tertiary-butylaminobromosilane, other organoaminosilanes containing halogen(s) or pseudohalogen(s), trimethylsilyl amine, trimethylsilyl dimethylamine, other alkylsilyl amines.

In another aspect, the method of growing thin films containing nitrogen includes providing a substrate within a chamber optionally contacting the substrate with hydrazine to create silicon nitride bonds on a surface of the substrate, contacting the substrate with a titanium precursor, such as titanium tetrachloride (TiCl₄), to deposit a layer of TiN onto the surface of the substrate, and contacting the substrate and the deposited layer with plasma to form film that is substantially oxygen free. The method may further include purging the chamber with nitrogen gas between each of the contacting steps for a pre-determined amount of time prior to commencing the next step. For example, after contacting with hydrazine as a pre-treatment step, the substrate may be exposed to TiCl₄ for about 1 s, followed by a 30 s nitrogen purge, followed by contact with anhydrous hydrazine for a predetermined amount of time, followed by a 30 s nitrogen purge, and contacting with argon plasma for about 1-10 s, where each of the processing steps is performed at about 300° C.-410° C. In various embodiments, the step of performing a cycle for layer deposition is repeated to increase thickness on the substrate, such as repeating the step about 20-450 times. In various embodiments, the step of performing a cycle for layer deposition is repeated 400 times. In certain embodiments, the cycle includes a nitrogen purge following each of the aforementioned exposing steps. As above, the step of contacting with plasma may be performed after multiple A-B cycles that do not individually include a plasma step, may be performed as a termination step to complete the ALD process, or may be performed as an intermediate step after a sufficient number of A-B cycles followed by another set of AB cycles.

Exemplary titanium precursors include, but are not limited to, titanium tetrachloride (TiCl₄), other titanium halides, titanium isopropoxide (TTIP), tetrakis(dimethylamino)titanium (TDMAT), tetrakis(diethylamino)titanium (TDEAT), tetrakis(ethylmethylamino)titanium (TEMAT), tri(dimethylamino)-(dimethylamine-2-propanolato)titanium (TDMADT) and cyclopentadienyl-based titanium derivatives.

### Example 1

### Silicon Nitride (SiN) Thin Film on a Silicon-Germanium Substrate

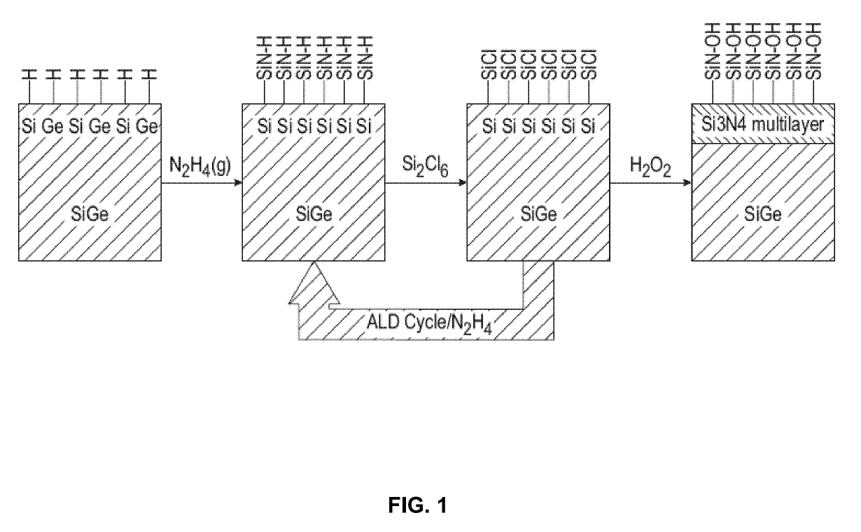

FIG. 1 depicts an exemplary process employed to grow a silicon nitride (SiN) thin film on a silicon-germanium substrate (Si_{0.5}Ge_{0.5}(110)). In this process, the surface was first cleaned to create a SiGe hydride surface. Hydrazine (N₂H₄) was then introduced to create silicon nitride bonds, which was followed by introduction of hexachlorodisilane (Si₂Cl₆) to add silicon to the growing SiN layer. The hydrazine and hexachlorodisilane were repeated to increase the thickness of the SiN layer, which was followed by addition of hydrogen peroxide (H₂O₂) cap the SiN layer. The source of hydrazine gas for this process was a non-aqueous hydrazine solution as described herein, which was delivered to the process.

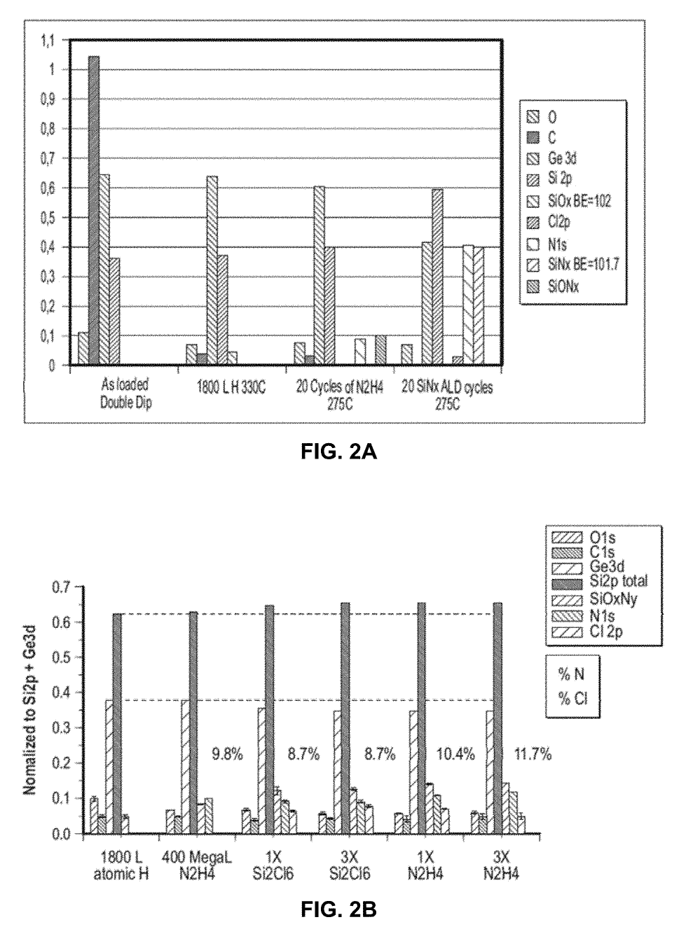

The substrate was subjected to x-ray photoelectron spectroscopy (XPS) at several stages to measure the relative concentration of different species on the surface during the ALD process. As shown in FIG. 2A: As loaded Double Dip are the results at the beginning of the process; 1800L H 330 C are the results after treating the surface with 1800 L of hydrogen at 330° C. to atomically clean the surface; 20 Cycles of N2H4 275 C are the results after subjecting the surface to 20 cycles of hydrazine at 275° C., with each cycle constituting 20 mega liters (ML) of hydrazine; and 20 SiNx ALD cycles 275 C are the results after subjecting the surface to 20 cycles of hexachlorodisilane at 275° C. followed immediately by hydrazine at 275° C., with each cycle constituting 13.5 ML of hexachlorodisilane followed by 20 ML of hydrazine. The silicon (2p) binding energy peak shift from 102 eV to 101.7 eV is consistent with growth of silicon nitride as Si3N4. Based on these results, it was estimated that the process yielded about 3-4 monolayers of silicon nitride with a growth rate of about 0.4 A per ALD cycle.

In another example, a silicon-germanium substrate (Si_{0.7}Ge0.3(001)) was used to grow SiN according to the ALD process described above. The substrate was subjected to x-ray photoelectron spectroscopy (XPS) at several stages to measure the relative concentration of different species on the surface during the ALD process. As shown in FIG. 2B: 1800L atomic H are the results after treating the surface with 1800 L of hydrogen at 330° C. to atomically clean the surface; 400 MegaL N₂H₄ are the results after subjecting the surface to 20 cycles of hydrazine at 275° C., with each cycle constituting 20 ML of hydrazine; 1× Si₂Cl₆ are the results after subjecting the surface to 13.5 ML of hexachlorodisilane at 275° C. after subjecting the surface to the above 20 cycles of hydrazine at 275° C.; 3× Si₂Cl₆ are the results after subjecting the surface to 3 cycles of hexachlorodisilane at 275° C. with each cycle constituting 13.5 ML of hexachlorodisilane and with the first 2 cycles followed by 20 ML of hydrazine at 275° C.; 1× N₂H₄ are the results after subjecting the surface to 20 ML of hydrazine at 275° C. after subjecting the surface to the above 1 cycle of hexachlorodisilane at 275° C.; and 3× N₂H₄ are the results after subjecting the surface to 3 cycles of hydrazine at 275° C., with each cycle constituting 20 ML of hydrazine and with the first 2 cycles followed by 13.5 ML of hexachlorodisilane at 275° C. Thus, silicon nitride grew on the surface with chlorine as a product in the form of HCl and there was some residual chlorine on the surface.

### Example 2

### SiN Deposition Studies

CVD and ALD of SiN are used in several applications including, gates, spacers, etch stops, liners, encapsulation layers as well as passivation layers. Recently, PEALD of SiN has taken on an increasingly important role due to new temperature constraints of 400° C. or less. However, several challenges remain on HAR and 3D structures in applications where plasma approaches may not meet conformality requirements. In addition, thermal ALD with NH₃ is not feasible due to the high temperature requirement (500° C.-700° C.) of these reactions.

The initial approach involves reaction of anhydrous hydrazine and hexachlorodisilane (Si₂Cl₆/HCDS) in order to develop methods for thermal ALD of SiN at about 410° C. or less. As demonstrated herein, the resulting films met the desired requirements of high growth rate, high density, and low wet etch rate similar to materials grown by thermal ammonia ALD at 600° C., or Ammonia PEALD at 400° C. In addition, the methods show promise for highly uniform growth on 3D and HAR structures where PEALD methods currently have difficulties.

In this example, the surface of a substrate was first cleaned to create a Si—H substrate. Hydrazine (N₂H₄) was then introduced to create silicon nitride bonds, which was followed by introduction of hexachlorodisilane (HCDS) to add silicon to the growing SiN layer. The hydrazine and hexachlorodisilane were repeated to increase the thickness of the SiN layer, and a comparison of the results was made to similar processing steps followed by argon plasma treatment. The source of hydrazine gas for this process was a non-aqueous hydrazine solution delivered to the process using an HDA as disclosed herein.

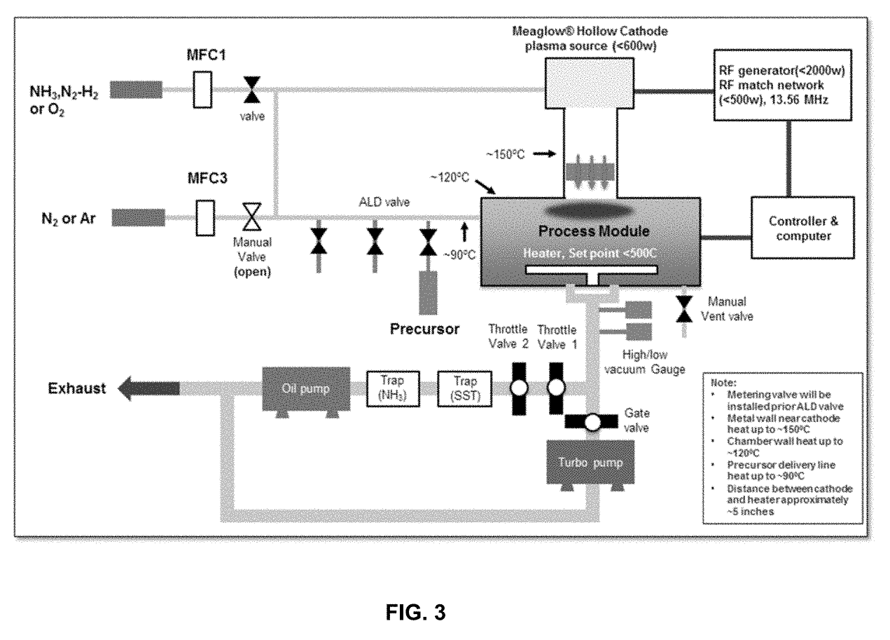

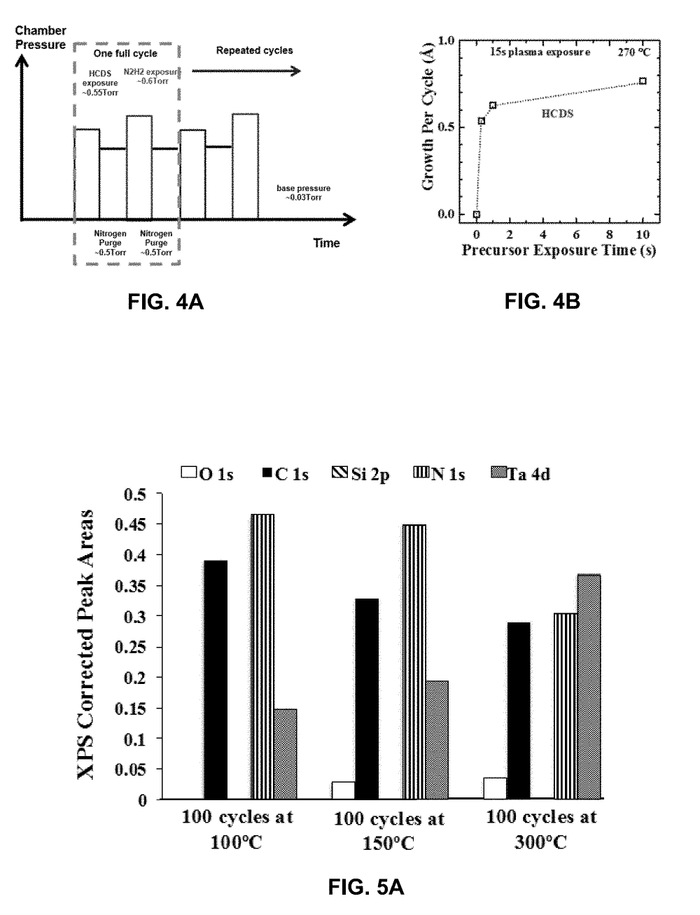

As shown in FIG. 3, a custom made thermal ALD reactor/chamber was used to deposit silicon nitride films at temperatures ranging from about 250° C. to about 410° C. Film growth per cycle (GPC) with hydrazine was about 0.4-0.5 Å/cycle at 400° C. with a refractive index of 1.813 (see FIGS. 4A and 4B). Film stoichiometry was confirmed with X-ray photoelectron spectroscopy (XPS). SiN films with low impurities were achieved for oxygen (<2%) and chlorine (<1%). Highly uniform films were obtained across a 4 inch wafer substrate for 200 as well as 400 cycles. Results were similar to films deposited using PEALD at 360° C. with HCDS and NH₃. Film growth and resulting properties at 350° C. closely resemble those grown thermally at 400° C. for hexachlorodisilane and hydrazine. Some discrete differences in film density and composition start to become apparent at a growth temperature of 325° C. Specifically, film density decreased and wet etch rate increased (see Table 1).

TABLE 1

| Run # | Film Density (g/cm³) |
|---|---|
| #3 (410° C.) | 2.44 |
| #10 (350° C.) | 2.45 |
| #11 (322° C.) | 2.34 |

The data presented herein compares growth rates, film density, refractive index and wet etch rate results at different temperatures, with “recipes” denoted with timing for each step as follows: HCDS-N₂-Hydrazine-N₂ (e.g., 1 s-30 s-X-30 s).

TABLE 2

| Run | Si | | | | | Thickness | GPC | | % NU | | | |
|---|---|---|---|---|---|---|---|---|---|---|---|---|
| # | Precursor | Temp | Recipe | Cycle | Carrier gas | (nm) | (A/cy) | Ri | (std dev) | 500:1 HF | | 100:1 HF |
| 1 | HCDS | 410 | 1-30-0.5-30 | 200 | N₂ (7/45 sccm~0.5 torr) | 7.40 | 0.37 | 1.786 | 2.28% | | | |
| 2 | HCDS | 410 | 1-30-0.1-30 | 200 | N₂ (7/45 sccm~0.5 torr) | 6.44 | 0.32 | 1.713 | 0.59% | | | |
| 3 | HODS | 410 | 1-30-0.5-30 | 400 | N₂ (7/45 sccm~0.5 torr) | 16.85 | 0.42 | 1.798 | 0.83% | 11 | nm/min | |
| 4 | HCDS | 410 | 1-30-2-30 | 200 | N₂ (7/45 sccm~0.5 torr) | 11.43 | 0.57 | 1.832 | 0.52% | | | |
| 5 | HCDS | 410 | 1-30-2-30 | 400 | N₂ (7/45 sccm~0.5 torr) | 20.08 | 0.53 | 1.813 | 2.18% | 10 | nm/min | |
| 6 | HCDS | 410 | 1-30-10-30 | 96 | N₂ (7/45 sccm~0.5 torr) | 6.91 | 0.72 | 1.770 | 1.24% | | | |
| 7 | HCDS | 410 | 1-30-0.5-30 | 200 | N₂ (7/45 sccm~0.5 torr) | 8.68 | 0.43 | 1.759 | 0.93% | | | |
| 8 | HCDS | 410 | [20 × (1-30)] − | 200 | N₂ (7/45 sccm~0.5 torr) | 8.97 | 0.45 | 1.767 | 1.61% | | | |
| | | | (1-30-0.5-30) | | | | | | | | | |
| 9 | HCDS | 410 | [60 × (1-30)] − | 200 | N₂ (7/45 sccm~0.5 torr) | 9.17 | 0.46 | 1.780 | 2.53% | | | |
| | | | (1-30-9.5-30) | | | | | | | | | |
| 10 | HCDS | 350 | 1-30-0.5-30 | 400 | N₂ (7/45 sccm~0.5 torr) | 19.26 | 0.48 | 1.79 | 1.10% | 25 | nm/min | |
| 11 | HCDS | 320 | 1-30-0.5-30 | 400 | N₂ (7/45 sccm~0.5 torr) | 19.68 | 0.49 | 1.785 | 1.65% | 50 | nm/min | |
| 12 | HCDS | 410 | 1-30-0.5-30-10 P | 400 | Ar (5/25 sccm~0.5 torr) | 16.31 | 0.41 | 1.907 | 2.36% | 0.5 | nm/min | |

Thus, increasing hydrazine exposure reduced oxygen content by 1% with a reduction in chlorine that was still within XPS detection limits. Table 3 shows detected elemental composition at various deposition temperatures.

TABLE 3

| | 410° C. | 350° C. | 322° C. |
|---|---|---|---|
| Si | 46.3% | 45% | 45% |
| N | 51.3% | 52% | 52% |
| O | 1.8% | 2% | 2% |
| C | <1% | <1% | <1% |
| CL | <1% | ~1.2% | 2% |

As shown in Table 2, Run #10 had a GPC of 0.48 A/cy measured at 350° C. The resulting film showed good uniformity (1.10%) and similar RI (1.790) compared to the results obtained from deposition at 410° C. Run #11 had a GPC of 0.49 A/cy measured at about 320° C. (for example at 322° C.). The resulting film showed good uniformity (1.65%) and similar RI (1.785) compared to the results obtained from deposition at 410° C. Run #12 occurred at 410° C. and followed an A-B-C cycle, which included 1 second of HCDS, followed by a 30 second nitrogen purge, then 0.5 seconds of hydrazine, followed by a 30 second nitrogen purge, then 10 seconds of argon plasma treatment at the end of each cycle. The resulting film from the A-B-C cycle (which included argon plasma treatment) had a GPC of 0.41 A/cy measured at 410 and similar RI (1.790) compared to the results obtained from deposition at 410° C. The resulting film showed good uniformity (2.36%) with a higher RI (1.907) compared to run #3 (1.798). However, the WER was significantly reduced to 0.5 nm/min from 11 nm/min (Run #3).

Thus, the A-B-C cycle was repeated at 350° C. for 400 cycles, and a GPC of 0.46 A/cy was measured. The resulting film showed a uniformity of 5.16%, but had a higher RI (1.907) compared to Run #10 (1.790). However, the WER (500:1 HF) was 0.3 nm/min compared to 25 nm/min of Run #10. The data presented herein therefore demonstrates that lower wet etch rates are obtained for films grown at reduced temperatures.

### Example 3

### TiNx Deposition Studies

Titanium nitride (TiN) has been extensively implemented in semiconductor devices because of its ideal thermal, mechanical, and electrical properties, along with its ability to act as a diffusion barrier to WF6 during W metal fill. Ti halide precursors are typically preferred over organometallic grown films when there is no concern about substrate etching, however, reactions for TiCl₄ with NH₃ give rise to poor film quality and high electrical resistance below 400° C. Thermally grown films with the use of NH₃ and a Metal-Organic precursor usually contain higher levels of carbon and oxygen contamination, which has also been correlated with an increase in film resistivity. Plasma enhanced-ALD TiN has been shown to achieve optimal growth rates with lower contamination at temperatures below 350° C., but the film and underlying substrate can suffer from plasma-induced damage.

The substrates used in this study consisted of 300 nm of thermal SiO2 grown on Si(001) (University Wafer). Samples underwent an ex situ degrease involving quick rinses in acetone, methanol, and water before being loaded into the vacuum chamber. Once loaded into the UHV chamber, the samples were heated to 350° C. for 30 minutes to remove any physisorbed surface contamination. Precursor exposures were performed in a deposition chamber, as described above. The deposition chamber and dosing lines were pumped with a turbomolecular pump, but the actual deposition was performed through only a backing pump with a base pressure of ˜1×10⁻² Torr. The chamber was heated ˜100° C., and dosing lines were kept ˜10-20° C. warmer to ensure precursors would not condense on the chamber walls. In addition, the N₂H₄ vessel was pressurized to ˜750 torr with ultrahigh purity N₂ that was passed through a purifier to act as a push gas for the N₂H₄. NH₃ from Praxair with a purity of 99.9% was used for TiNx experiments undiluted. Precursor exposures are presented in MegaLangmuirs (MLs where 1 ML=1×10⁻⁶ Ton for 1 sec), and were calculated from exposure time and pressure of the precursor; however, it should be noted that the values presented for exposures of N₂H₄ do not account for the dilution with N₂. As an estimation, by using the vapor pressure of N₂H₄ at room temperature, the amount of N₂H₄ was likely ˜1-2% of the total exposure.

Before moving samples into the deposition chamber, samples were preheated in the UHV chamber. In both chambers, samples were radiatively heated by a pyrolytic boron nitride (PBN) heater. After exposure to anhydrous N₂H₄ (Rasirc) and either TiCl₄ (Strem Chemicals), TDMAT (Sigma-Aldrich), or TBTDET (Sigma-Aldrich) samples were transferred back to the UHV chamber where in situ x-ray photoelectron spectroscopy (XPS) was performed without breaking vacuum. A monochromatic XPS system (A1 kα hv=1486.7 eV) was used to collect surface-sensitive spectra at an angle of 60° with respect to the surface normal. Additionally, an electron pass energy of 50 eV and a line width of 0.1 eV were used. XPS spectra analysis was conducted with CASA XPS v.2.3 utilizing Shirley background subtractions. Schofield photoionization cross sectional relative sensitivity factors were used to correct raw peak areas. In addition to XPS, surface topography was characterized with atomic force microscopy (AFM). Lastly, the resistance of air-exposed thin films was measured using a modified four-point probe measurement, in which 30 nm thick Ni dots with 150 μm diameters and 250 μm spacing were deposited on top of ALD TiNx and TaNx films. Resistivities were approximated by estimating the thickness of deposited films from cross-sectional scanning electron microscopy (SEM) images. Note the resistivities were measured after air exposure so the actual TiNx thicknesses are probably less than those measured by SEM since the top few nanometers may have been oxidized and converted to high resistivity TiOxNy.

TaNx from TBTDET

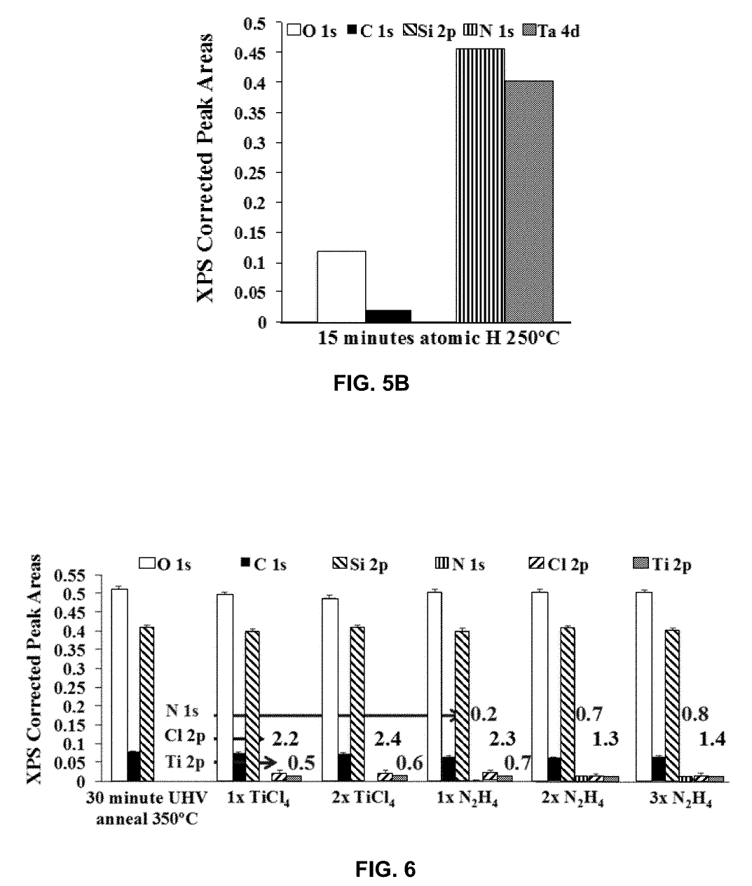

Anhydrous N₂H₄ chemistry was applied to ALD at very low temperatures with an organometallic Ta precursor (TBTDET). AFM imaging indicated a pinhole-free surface with a low RMS surface roughness of 0.25 nm from 15 cyclic exposures of TBTDET and N₂H₄ at 150° C. XPS of TaNx films at temperatures between 100° C. and 300° C. showed that the films contain nearly 40% C at 100° C. and almost 30% at 300° C. (FIG. 5A); however, the amount of a is undetectable at 100° C. and only ˜4% at higher temperature. A raw Ta 4 d XPS peak after 6 pulses of TBTDET and after 15 TaNx cycles confirmed the nucleation with TBTDET (Si—O—Ta formation) based on the Ta 4 d peak position of ˜231 eV. After ALD cycles of TBTDET+N₂H₄, there was an ˜2 eV chemical shift toward lower binding energy consistent with formation of Ta—N bonds in the film. It is noted that the ratio of Ta to N in the deposited films becomes more Ta rich at increasing deposition temperatures. This effect was observed more clearly when looking at the Ta 4p_{3/2}/N 1 s region; at higher temperature the N peak shifts to lower BE and becomes more narrow while the Ta component increased in intensity. 15 minutes of atomic H was performed on the 150° C. grown film and was shown to be sufficient to remove the carbon that was accumulating on the surface during deposition. The C was significantly reduced to ˜1.5% (FIG. 5B).

XPS was performed after subsequent cycles of TaNx ALD at 100° C. After 100 total cycles at a deposition temperature of 100° C. followed by UHV anneals at 150° C., 200° C., and 250° C. each for 30 minutes. During the ALD dosing, there was a broad N is component located at a BE of ˜399 eV along with a very weak Ta 4p_{3/2} signal at ˜404 eV. Upon annealing, the Ta 4p_{3/2} component became stronger, and the N 1 s peak narrowed and shifted toward lower BE. This observed change in the N 1 s peak is consistent with the loss of surface CHₓN_{y} surface species and consistent with the formation of partially crystalline Ta₃N₅ as previously reported.

When trying to determine the precise oxidation state of the Ta to ascertain if the film is more like conductive TaN or insulating Ta₃N₅, it is not sufficient to just analyze the Ta 4p region; further evidence of Ta being in an oxidation state higher than +3 can be seen when looking at the peak position of the Ta 4f From the literature, this corresponds much closer to an average oxidation state of at least Ta+4. Lastly, resistance measurements were performed on several TaNx samples; measurements indicated highly resistive films consistent with higher oxidation state Ta TaNx films.

TiCl₄

FIG. 6 shows the XPS results from saturation dosing that was performed on SiO₂/Si at 300° C. After undergoing a UHV anneal at 350° C., the first 1× exposure of 10 ML TiCl₄ was dosed and reacted on the surface, evidenced by the 0.5% Ti and 2.2% Cl seen in XPS. Subsequently, an additional 2× exposure of 20 ML TiCl₄ saturated the Ti at 0.6% and Cl at 2.4%. In a similar manner, N₂H₄ saturation dosing was performed using subsequent exposures to a 1×, 2×, and 3× dose where a 1× exposure equals 15 ML of N₂H₄ diluted in N₂. After the final 3× dose, the Cl dropped from 2.4% to 1.4%, and the N saturated at 0.8%. This evidence of saturating half-cycle dosing is consistent with a low-temperature thermal ALD procedure utilizing 10 ML TiCl₄+45 ML N₂H₄.

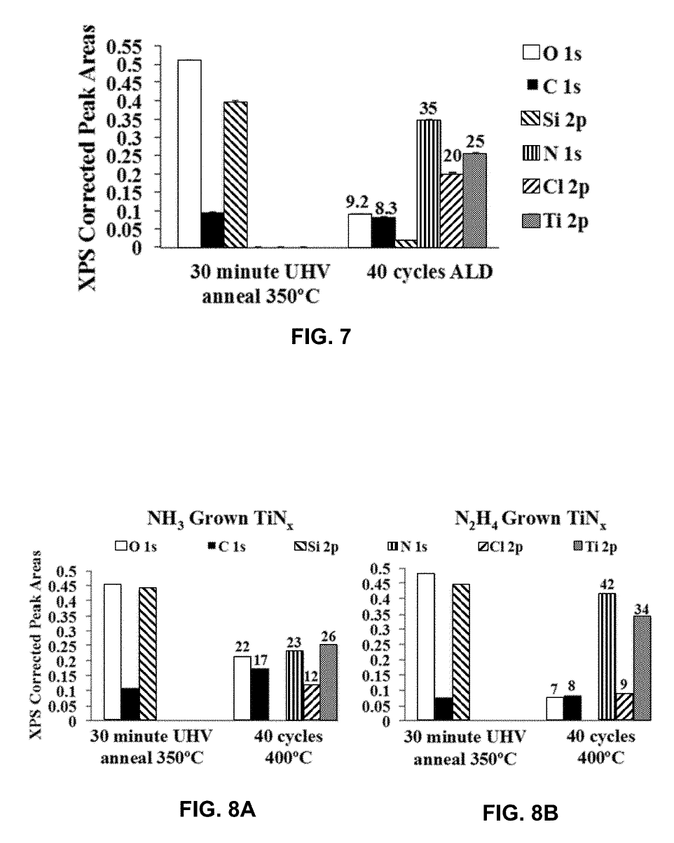

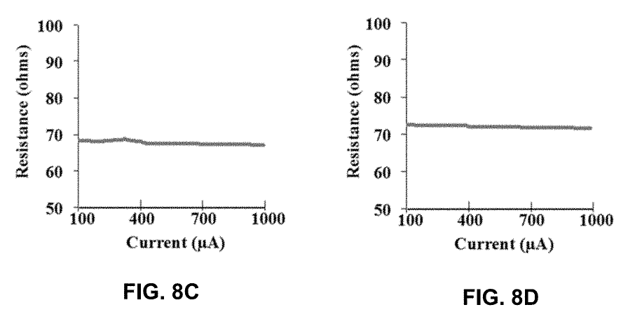

Once the required pulse size of each half-cycle was determined from the saturation study, thicker films of TiNx were grown using the saturated recipe of 10 ML TiCl₄ and 45 ML N₂H₄. FIG. 7 shows the corrected and normalized XPS of 40 cycles TiNx at 300° C. The composition of the 40 cycles film indicated that there was ˜20% residual Cl that could be left in the film or on top of the film as a Cl selvedge layer; however, the chemical shift data for Ti showed only a small Ti—Cl component in the bulk of the film, consistent with the residual Cl mainly being a surface layer. The level of attenuation of the Si 2p substrate is consistent with 40 cycles being ˜5 nm thick.

An observed lower binding energy (BE) component located at ˜455 eV was consistent with Ti—N bonds, as previously reported; it is also known that stoichiometric TiO2 has a BE near 458-459 eV. Additionally, since, the deposited film also contains Cl residue, Cl bonds cannot be neglected and are known to have a BE of ˜458.5 eV as well. Therefore, the component that is located at ˜456.5 eV is consistent with a higher N content TiNx (likely Ti₃N₄) or a substoichiometric TiOx. However, as shown in Table 4, the high conductivity of the films is consistent with only trace TiOx in the bulk of the film. It should be noted that precise fitting of the Ti 2p peak was difficult due to the numerous Ti chemical states, as well as the wide range of XPS BE values reported in the literature for TiN, TiNx, and TiOxNy films. Therefore, for definitive documentation of deposition of TiN, resistivity measurements are required.

In order to perform four-point probe measurements to check the resistivity of deposited films, TiNx films were exposed to ambient air conditions for ˜1 hour. To quantify the effect of the air exposure, XPS was performed after 1 minute, 5 minutes and 60 minutes of ambient exposure. Along with increasing the amount of surface oxygen and carbon, the oxidation state of the Ti underwent a significant shift. Before ambient exposure, the maximum of the Ti 2p 3/2 peak appeared at 456 eV with a strong TiN component at 455 eV; however, even after just 1 minute of air exposure, O attacked the TiNx film, evidenced by observing an ˜1.5 eV BE shift of the Ti 2p 3/2 peak. After 60 minutes of air exposure, the maximum peak position shifted by about 2 eV, as well as a significant decrease in the TiN component at ˜455 eV. Additionally, this oxidation could increase the film thickness that was determined with SEM. Both of these effects would be expected to lead to increases in the reported resisitivites in this manuscript, as compared to hypothetical resistivity measurements in situ.

To characterize the surface topography, AFM was performed on the 40 cycles of ALD TiNx film. AFM imaging along with corresponding line traces show the pinhole-free AFM image of 40 cycles of TiNx at 300° C. compared with the bare SiO2 surface. Additionally, the deposition was uniform as evidenced by maintaining a low RMS surface roughness of 0.44 nm.

To study the efficacy of N₂H₄ as a TiN precursor, thermal NH₃ at 400° C. was used for comparison. There was approximately 2× more O and C and 50% more Cl in NH₃ grown films. Table 4 summarizes the results of TiNx films utilizing TiCl₄ and either N₂H₄ or NH₃. N₂H₄ films showed lower resistivities, attributed to lower contamination and likely better nucleation density. The best result of 400° C. N₂H₄ showed the lowest residual Cl at 8.7%, which correlated with being the lowest resistivity film estimated at 359 μohm-cm. From the air exposure XPS study, approximately the top 2 nm of the TiNx films were converted to TiOxNy/surface contamination; thus the thickness of TiNx may be as low as 9 nm so the intrinsic resistivity could equate to as low as 294 μohm-cm for the 400° C. N₂H₄ film.

TABLE 4
Summary of TiNx Films Grown with NH₃ and N₂H₄

| Nitrogen | Temperature | Residual | Number of | SEM | Growth Rate | Resistivity |
|---|---|---|---|---|---|---|
| Precursor | (° C.) | Chlorine (%) | Cycles | Thickness | (nm/cycle) | (μohm-cm) |
| NH₃ | 300 | 16.0 | 80 | 13 | 0.16 | 2,885 |
| NH₃ | 400 | 12.1 | 40 | 18 | 0.45 | 554 |
| N₂H₄ | 300 | 18.1 | 80 | 17 | 0.21 | 593 |
| N₂H₄ | 400 | 8.7 | 40 | 11 | 0.28 | 359 |

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of growing a thin film comprising:
(a) providing a substrate within a chamber heated to about 300° C.-410° C.;
(b) pre-treating the substrate with anhydrous hydrazine, thereby creating silicon nitride bonds on a surface of the substrate; and
(c) performing a cycle for layer deposition on the pre-treated substrate, wherein the cycle comprises:
(i) exposing the substrate to one or more silicon precursors;
(ii) thereafter, exposing the substrate to anhydrous hydrazine; and
(iii) thereafter, exposing the substrate to plasma,
thereby depositing a layer of SiN onto the surface of the substrate, wherein the deposited layer forms a film that is substantially oxygen free.

2. The method of claim 1, wherein the one or more silicon precursors are independently selected from the group consisting of hexachlorodisilane (Si₂Cl₆), chlorosilane (SiH₃Cl), dichlorosilane (SiH₂Cl₂), trichlorosilane (SiHCl₃), silicon tetrachloride (SiCl₄), octachlorotrisilane (Si₃Cl₈), silicon tetrabromide (SiBr₄), silicon tetraiodide (SiI₄), other silicon halides or silanes containing pseudohalogen(s), trisilylamine (TSA), tris(dimethylamino)silane (3DMAS), Bis(tertiary-butylamino)silane (BTBAS) and di(sec-butylamino)silane (DSBAS), di(isopropylamino)silane (DIPAS), bis(diethylamino)silane (BDEAS), tris(isopropylamino)silane (TIPAS), other organoaminosilanes, silane (SiH₄), disilane (Si₂H₆), trisilane (Si₃H₈), neopentasilane (Si₅H₁₂), other silanes or substituted silanes containing multiple Si atoms, dimethylaminochlorosilane, tertiary-butylaminobromosilane, other organoaminosilanes containing halogen(s) or pseudohalogen(s), trimethylsilyl amine, trimethylsilyl dimethylamine, other alkylsilyl amines.

3. The method of claim 2, wherein the silicon precursor is Si₂Cl₆.

4. The method of claim 1, wherein step (c) is repeated about 20-450 times.

5. The method of claim 1, wherein step (c) further comprises a nitrogen purge following each of steps (i), (ii), and (iii).

6. The method of claim 1, wherein steps (i) and (ii) are repeated a plurality of times before performing step (iii).

7. The method of claim 1, wherein the chamber is heated to about 300° C.-410° C.

8. The method of claim 1, wherein the anhydrous hydrazine is delivered in a gas stream produced from a hydrazine solution that contains less than about 50 parts-per-million of water.

9. The method of claim 8, wherein the gas stream has less than 1 ppm, 100 ppb, 10 ppb or 1 ppb water vapor.

10. The method of claim 8, wherein the hydrazine solution further comprises a solvent selected from polymers or oligomers of polyaniline, polypyrrole, polypyridine or polyvinylalcohol, wherein the viscosity of the solution is about 35 cp or less.

11. The method of claim 8, wherein the hydrazine solution further comprises a solvent selected from ethylene glycol, diethylene glycol, triethylene glycol, monoglyme, diglyme, triglyme, higlyme, tetraglyme, Polyglycol DME 200, Polyglycol DME 250, Polyglycol DME 500, Polyglycol DME 1000, Polyglycol DME 2000, hexamethylphosoramide, DMPU, DMEU, TMU, or hexamethylenetetramine.

12. The method of claim 1, wherein the anhydrous hydrazine is purified prior to contact with the substrate.

13. The method of claim 1, wherein step (c) consists of the following steps in the following order:
(i) exposure to hexachlorodisilane at about 0.55 Torr for about 1 second;
(ii) exposure to a first nitrogen purge for 30 seconds;
(iii) exposure to anhydrous hydrazine at about 0.6 Torr for about 0.5 seconds;
(iv) exposure to a second nitrogen purge for 30 seconds; and
(v) exposure to argon plasma for about 10 seconds.

14. A method of growing a thin film comprising:
(a) providing a substrate within a chamber heated to about 300° C.-410° C.;
(b) pre-treating the substrate with anhydrous hydrazine, thereby creating silicon nitride bonds on a surface of the substrate; and
(c) performing a cycle for layer deposition on the pre-treated substrate, wherein the cycle comprises:
(i) exposing the substrate to one or more titanium precursors;
(ii) thereafter, exposing the substrate to anhydrous hydrazine; and
(iii) thereafter, exposing the substrate to plasma,
thereby depositing a layer of TiN onto the surface of the substrate, wherein the deposited layer forms a film that is substantially oxygen free.

15. The method of claim 14, wherein the titanium precursors are independently selected from the group consisting of titanium tetrachloride (TiCl₄), titanium tetrabromide (TiBr₄), titanium tetraiodide (TiI₄), other titanium halides, titanium isopropoxide (TTIP), tetrakis(dimethylamino)titanium (TDMAT), tetrakis(diethylamino)titanium (TDEAT), tetrakis(ethylmethylamino)titanium (TEMAT), tri(dimethylamino)-(dimethylamine-2-propanolato)titanium (TDMADT) and cyclopentadienyl-based titanium derivatives.

16. The method of claim 15, wherein the titanium precursor is TiCl₄.

17. The method of claim 14, wherein step (c) is repeated about 20-450 times.

18. The method of claim 14, wherein step (c) further comprises a nitrogen purge following each of steps (i), (ii), and (iii).

19. The method of claim 14, wherein steps (i) and (ii) are repeated a plurality of times before performing step (iii).

20. The method of claim 14, wherein the chamber is heated to about 300° C.-410° C.

21. The method of claim 20, wherein the anhydrous hydrazine is delivered in a gas stream produced from a hydrazine solution that contains less than about 50 parts-per-million of water.

22. The method of claim 21, wherein the gas stream has less than 1 ppm, 100 ppb, 10 ppb or 1 ppb water vapor.

23. The method of claim 21, wherein the hydrazine solution further comprises a solvent selected from polymers or oligomers of polyaniline, polypyrrole, polypyridine or polyvinylalcohol wherein the viscosity of the solution is about 35 cp or less.

24. The method of claim 21, wherein the hydrazine solution further comprises a solvent selected from ethylene glycol, diethylene glycol, triethylene glycol, monoglyme, diglyme, triglyme, higlyme, tetraglyme, Polyglycol DME 200, Polyglycol DME 250, Polyglycol DME 500, Polyglycol DME 1000, Polyglycol DME 2000, hexamethylphosoramide, DMPU, DMEU, TMU, or hexamethylenetetramine.

25. The method of claim 14, wherein the anhydrous hydrazine is purified prior to contact with the substrate.

26. The method of claim 14, wherein step (c) consists of the following steps in the following order:
(i) exposure to TiCl₄ at about 0.55 Torr for about 1 second;
(ii) exposure to a first nitrogen purge for 30 seconds;
(iii) exposure to anhydrous hydrazine at about 0.6 Torr for about 0.5 seconds;
(iv) exposure to a second nitrogen purge for 30 seconds;
(v) exposure to argon plasma for about 10 seconds.
